(19) United States
(12) Patent Application Publication
(10) Pub. No.: US 2023/0181951 A1
(43) Pub. Date: Jun. 15, 2023

(54) PRESSURE RELIEF DEVICE

(71) Applicant: R. STAHL SCHALTGERÄTE GMBH, Waldenburg (DE)

(72) Inventors: Elena KONDRUS, Künzelsau (DE); Holger SEMRAU, Satteldorf (DE)

(21) Appl. No.: 17/923,704

(22) PCT Filed: Apr. 29, 2021
(86) PCT No.: PCT/EP2021/061298

§ 371 Date: Nov. 7, 2022

(30) Foreign Application Priority Data
May 8, 2020 (DE) 10 2020 112 499.6

(51) Int. Cl. A62C 4/00; H05K 5/02

(52) U.S. Cl. CPC A62C 4/00; H05K 5/0213

(57) ABSTRACT

A pressure relief device for an explosion-proof housing. The pressure relief device has a lamellae arrangement having a plurality of lamellae. The lamellae are arranged in a transverse direction with distance to one another and thereby limit flow channel between two lamellae respectively. Each flow channel establishes a flow connection between a first opening and a second opening of the lamellae arrangement that are arranged with distance to one another in flow direction. Each flow channel has a non-straight preferably meandering or wave-shaped extension between the first opening and the second opening and can be flameproof as an option. Water drops that accumulate inside the flow channel are retained due to the contact with the two adjacent lamellae due to adhesion forces. In doing so, the pressure relief device is configured as protection against throughflow of water without additional measures.

### CROSS REFERENCE TO RELATED APPLICATIONS

This application is a National Stage of PCT Application No. PCT/EP2021/061298 filed on Apr. 29, 2021, which claims priority to German Patent Application No. 10 2020 112 499.6 filed on May 8, 2020, the contents each of which are incorporated herein by reference thereto.

### TECHNICAL FIELD

The invention refers to a pressure relief device for an explosion-proof housing.

### BACKGROUND

The pressure relief device is configured to allow a gas flow between the interior of an explosion-proof housing and an explosive environment, which is present outside the housing. In case of an explosion the pressure in the interior of the housing can be limited by means of the pressure relief device on one hand. During operation of electrical and/or electronic devices in the interior of the housing a gas circulation between the interior and the environment can be created on the other hand in order to dissipate heat from the interior.

EP 2 503 199 B1 shows a pressure relief device having a filter function. For this an open-pored element is present, e.g. a fleece material. The average pore diameter shall be between 2 and 100 μm. The fleece material shall be lipophobe and hydrophobe.

DE 20 2005 011 301 U1 discloses a breathable cable or hose feedthrough that is hygroscopic on one side. In order to be breathable and to avoid ingress of water, a semi-permeable membrane valve is arranged in an air channel.

Also DE 10 2005 047 662 B4 describes a pressure relief threaded arrangement having a pressure relief element comprising a membrane.

The pressure relief device known from DE 10 2010 016 782 B4 comprises a porous body inside the gas flow path. For example, the porous body can be formed of multiple layers of wire meshes. As an option, in addition a membrane can be present in order to close the gas flow path, e.g. a polymer having hydrophilic and hydrophobic sections.

In DE 10 2016 003 780 A1 a housing for an electrical device is described. A gas flow path between an interior and the environment passing through a fiber body can be established. The fiber body shall protect against the ingress of gushing water or splashing water. It shall also serve as burst protection and shall be at least partly pushed out of its holder in case of an explosion.

When constructing explosion-proof housings a conflict frequently exists. On one hand, the ignition sources arranged in the interior of the explosion-proof housing shall be separated from the explosive atmosphere in the environment, on the other hand a gas flow for pressure limitation or pressure balancing as well as for heat transfer is desired or required in many cases. Depending on the environmental conditions, it can thereby be necessary to protect the gas flow path in order to prevent ingress of water, particularly splashing water or hose water. Such a protection can in turn limit the volume flow rate of gas along the gas flow path, which is in turn not desired.

### BRIEF SUMMARY

Therefore, it can be considered as object of the present disclosure to provide an ignition-proof pressure relief device that forms a protection against ingress of splashing water and/or hose water and that, however, allows a high volume flow rate of the gas flow.

This object is solved by means of a pressure relief device configured to be used in a gas flow path between an interior of an explosion-proof housing and an explosive environment, the pressure relief device, including: a lamellae arrangement comprising multiple lamellae, wherein the lamellae arrangement comprises a first opening and a second opening that is in flow connection with the first opening in a flow direction, wherein the multiple lamellae extend between the first opening and the second opening, wherein each lamella of the multiple lamellae has multiple bends and/or sharp bends and wherein two directly adjacent lamellae of the multiple lamellae limit a non-straight flow channel respectively.

According to the present disclosure, the pressure relief device is configured to be arranged in a gas flow path. The gas flow path allows a gas flow between an interior of an explosion-proof housing and an explosive atmosphere in the environment. For example, the pressure relief device can be inserted in a wall opening of the housing.

The pressure relief device includes a lamellae arrangement having a first opening and a second opening that is in flow connection with the first opening. Gas can flow between the two openings in a flow direction. The flow direction is particularly a direction orientated orthogonal to a plane, which is orientated parallel to the first opening and the second opening. The flow direction is orientated particularly orthogonal to a plane parallel to the housing wall through which the gas flow path is established.

The lamellae arrangement includes multiple lamellae that are arranged orthogonal to the flow direction next to each other in a transverse direction. Two directly adjacent lamellae in transverse direction limit a common flow channel.

Each flow channel can be ignition proof as an option. The ignition-proof condition of each flow channel can be established in that the ratio of the flow cross-section divided through the path length along the flow channel is sufficiently small, such that the requirements of ignition-proof condition defined in the standards are fulfilled (particularly EN 60079-0). In doing so, the lamellae arrangement and thus the pressure relief device can be in addition configured in an ignition-proof manner.

Each lamella has several bends and/or angles. Therefore, a lamella does not extend completely along a straight line in flow direction between the first opening and the second opening, but at least in sections concurrently also in transverse direction. Preferably, the lamellae do not have a two-dimensional section that extends parallel to the flow direction. Due to this shape of the lamellae (preferably ignition-proof), flow channels are established that are not straight. The gas cannot flow through the flow channels parallel to the flow direction, at least not everywhere. Each flow channel can have two, three or more sites at which the gas flow along the flow channel changes the direction.

Due to the lamellae comprising bends and/or angles and the small channel width (distance between two directly adjacent lamellae in transverse direction) of the flow channels, a protection against ingress of water, particularly spraying water and/or splashing water and/or hose water, into the interior of the housing is achieved. Water drops may indeed enter into the flow channels, but due to the non-straight extending flow channels, hit against a side wall of a lamella limiting the flow channel. If multiple water drops accumulate, the accumulated or built up amount of water contacts both lamellae that limit the flow channel. Due to adhesion forces between the water and the lamellae, it is avoided that the water enters into the interior of the housing by completely passing through the flow channel.

The accumulated or built up water amount in a flow channel is relatively small and can evaporate or can be carried away over time, particularly by discharge of warm air out of the interior in direction toward the environment.

The pressure relief device can be manufactured in a simple manner. Due to the configuration of the lamellae or the flow channels, a protection against ingress of water according to an IP protection type (standard ISO20653 or EN60529) can be achieved. As an option, by means of the pressure relief device a configuration according to a standard complying explosion-proof category can also be achieved.

Particularly the pressure relief device does not comprise a separate, additional water barrier. The pressure relief device is preferably realized without porous body or membrane. Each flow channel limited by two lamellae can be an empty space without filling or membrane cover.

The explosion-proof housing comprising the pressure relief device can be configured, for example, in the explosion protection category flameproof enclosure (Ex d) according to one of the standards EN60079-1 or IIC60079-1.

The lamellae arrangement particularly comprises two outer lamellae and at least one inner lamella arranged between the two outer most lamellae. Preferably a plurality of inner lamellae is provided. Each inner lamella directly limits two flow channels. Each outer lamella only limits one flow channel with one side surface.

Preferably the pressure relief device is configured to allow a gas flow along a gas flow path through the flow channels exclusively. Additional gas flow openings are not present.

Preferably each lamella comprises at least three bends and/or angles. At each bend or at each angle the lamella includes an angle that is preferably less than 150° and further preferably less than 120°. The angles at multiple bend or angled locations of a lamella can have equal or different amounts respectively.

In an embodiment all of the lamellae of the lamellae arrangement are arranged symmetrically relative to a center plane. The center plane extends orthogonal to the gas flow direction and can be arranged, for example, in a manner centered between the first opening and the second opening.

In an embodiment each lamella comprises a first edge facing or being assigned to the first opening and a second edge facing or being assigned to the second opening. The first edge and the second edge can extend along a straight line in a height direction. The height direction is orientated orthogonal to the flow direction and orthogonal to the transverse direction.

Each lamella comprises in addition a third edge and a fourth edge that extend with distance to one another and connect the first edge and the second edge with each other respectively. The third edge and the fourth edge do not extend along a straight line. Preferably they have a wave-like and/or angled extension with multiple bend or angled sites.

Preferably the edges of the lamellae of the lamellae arrangement are arranged in a manner that all of the first edges are in contact with a common first plane, all of the second edges are in contact with a common second plane, all of the third edges are in contact with a common third plane and all of the fourth edges are in contact with a common fourth plane. The third plane and the fourth plane can extend parallel to one another. The first plane and the second plane can be orientated parallel to each other.

Preferably the first plane and the second plane are orientated orthogonal to the third plane and the fourth plane. With view in transverse direction the four planes limit a quadrangle, particularly a rectangle or square.

In transverse direction each flow channel has a channel width. In a preferred embodiment the channel width is constant.

In another embodiment one or more flow channels can have a local narrow at which the channel width in transverse direction is decreased and can have a local minimum. At the narrow the channel width or the flow cross-section of the flow channel is smaller than the maximum channel width or the maximum flow cross-section and/or is smaller than the average flow cross-section or the average channel width. By means of the at least one narrow, the stopping of accumulated water inside the flow channel can be improved. By means of the adhesion forces water accumulations are impeded to enter inside the interior in that they stick on both lamellae limiting the flow channel. Due to the local narrow, the water amount can be reduced that is necessary to achieve sticking on both lamellae. In that the flow channel comprises a reduced channel width only at one or multiple narrows, a sufficient volume flow rate for the gas flowing therethrough can be achieved.

It is preferred that each narrow is formed by a projection at least at one of the two lamellae limiting the flow channel. For example, the projection can be formed by means of a deformation process, e.g. a stamping process. Thus, the projection can be a deformation projection or stamping projection. Along the extension of the flow channel between the openings the projection can extend completely along the lamella. In addition or as an alternative, the projection can also be remarkably shorter than the flow channel in extension direction of the flow channel and can be formed, for example, by a nub-like projection.

Each flow channel has a first channel opening at the first opening and a second channel opening at the second opening. It is preferred, if both channel openings are arranged in alignment in flow direction.

It is in addition advantageous, if each lamella has a constant wall thickness. Preferably the wall thickness of all lamellae is equal.

Preferably the maximum and/or average channel width is at most 15 times or at most 10 times as large as the wall thickness. In doing so, a sufficient volume flow rate can be achieved with a concurrently small dimension of a lamellae arrangement in transverse direction.

The wall thickness of the lamellae is preferably maximum 2 mm or maximum 1 mm or maximum 0.7 mm. The maximum and/or average channel width is preferably not larger than 10 mm or 7 mm or 4 mm.

### BRIEF DESCRIPTION OF THE DRAWINGS

Advantageous embodiments of the invention are derived from the dependent claims, the description and the drawings. In the following preferred embodiments of the invention are explained in detail. The drawings show:

FIG. 1 a schematic sectional illustration of an explosion-proof housing having a pressure relief device according to the present disclosure,

FIG. 2 an embodiment of a pressure relief device in a schematic view in installed condition,

FIG. 3 a perspective view of a lamella of a pressure relief device from FIGS. 1 and 2,

FIG. 4 a schematic view of a flow channel of the pressure relief device according to FIGS. 1 and 2 that is limited by two adjacent lamellae,

FIG. 5 a perspective illustration in part of an embodiment of a pressure relief device according to FIG. 2 in partly installed condition,

FIG. 6 a perspective illustration in part of the embodiment of the pressure relief device of FIG. 5,

FIG. 7 a modified embodiment of the lamellae of the pressure relief device for forming of at least one narrow inside a flow channel in a schematic view and

FIGS. 8 and 9 a schematic side view in transverse direction onto a lamella respectively having at least one projection for forming a narrow.

### DETAILED DESCRIPTION

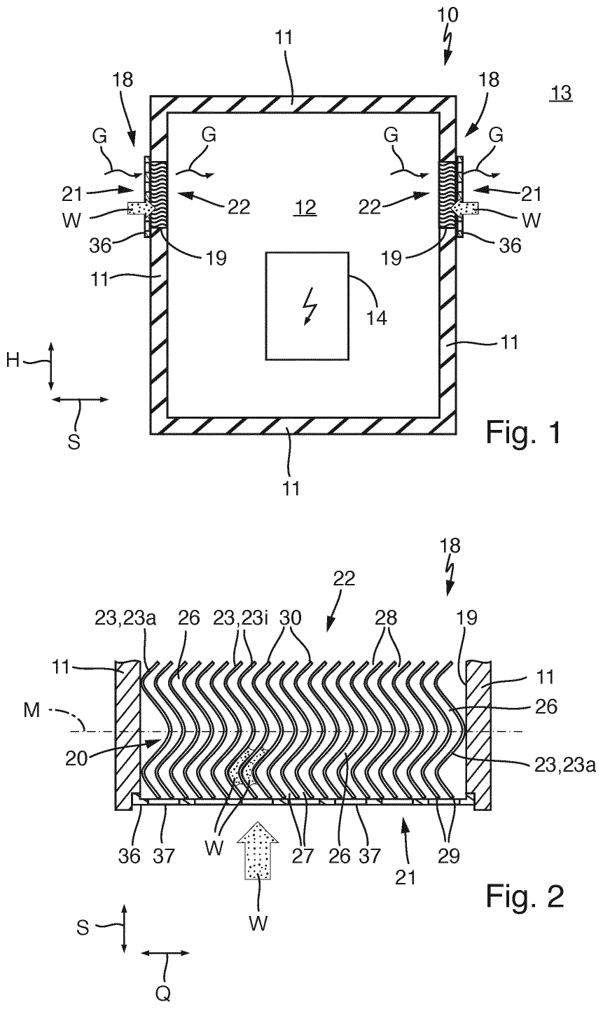

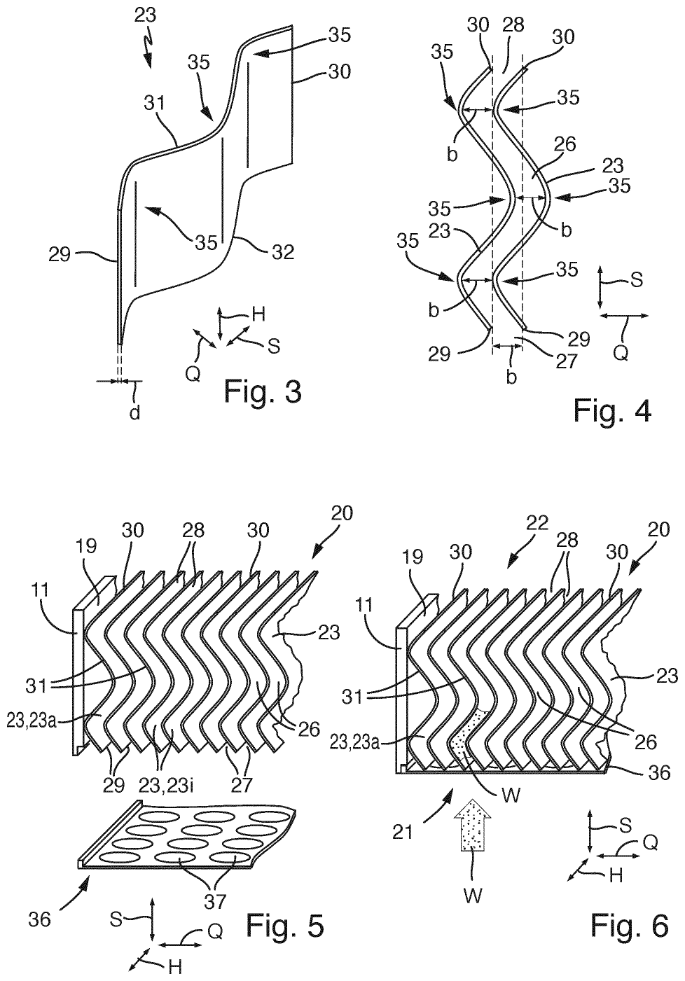

In FIG. 1 an explosion-proof housing 10 is schematically illustrated in cross-section. The explosion-proof housing 10 comprises multiple housing walls 11 that enclose an interior 12. By means of the explosion-proof housing 10 the interior 12 is separated from an explosive atmosphere in the environment 13 surrounding the housing 10 according to a predefined explosion protection category. The explosion-proof housing can be configured in the explosion protection category “flameproof enclosure (Ex d)”, for example.

In the interior 12 of the explosion-proof housing one or more devices that serve as ignition sources, such as electrical and/or electronic devices 14 can be arranged and operated. Hot gases, flames, ignition sparks or other ignition media cannot enter the environment 13 out of the interior 12 of the housing 10 to ignite the explosive atmosphere present in the environment 13.

The explosion-proof housing 10 comprises at least one pressure relief device 18. Each pressure relief device 18 can be arranged in a wall opening 19 inside a housing wall 11 or another flow channel between the interior 12 and the environment 13 and make or cover this flow channel in a flameproof manner. The pressure relief device 18 is configured to allow a gas flow along a gas flow path between the interior 12 and the environment and concurrently avoid escape of ignition media out of the interior 12 into the environment 13. In addition, the pressure relief device 18 is configured to impede the ingress of water, particularly spray water and/or splash water and/or hose water from the environment 13 into the interior 12 and corresponds to an IP protection type, e.g. one of the IP protection types IP3 to IP6 according to ISO20653 or EN60529.

For example, gas G can flow along the gas flow path from the environment 13 into the interior 12 and/or gas can flow from the interior 12 into the environment 13. In this manner also a heat transfer of warmer gases out of the interior 12 into the environment 13 can take place and cooler gas can flow from the environment 13 into the interior 12, e.g. in order to cool a device operated there and to limit heating of the housing walls 11.

According to the present disclosure, the pressure relief device 18 comprises a lamellae arrangement. The lamellae arrangement has a first opening 21 and a second opening 22 arranged with distance thereto in a flow direction S. The first opening 21 can face the environment 13, while the second opening 22 can face the interior 12. Both openings 21, 22 are orientated parallel to a common plane according to the example, wherein the flow direction S is orientated orthogonal to this plane. According to the embodiment, the flow direction S is orientated orthogonal to the housing wall 11 in which the pressure relief device 18 is located. Dependent on the arrangement of the pressure relief devices 18, flow directions S of different pressure relief devices 18 can be arranged parallel, inclined or orthogonal to one another.

The lamellae arrangement 20 comprises a plurality of lamellae 23 that are arranged in a row in a transverse direction Q with distance to one another. In transverse direction Q the two lamellae 23 that have the largest possible distance form an outer lamella 23a respectively. Between these two outer lamellae 23a multiple inner lamellae 23i are arranged.

In the embodiment all of the lamellae 23 are configured identically. They have the same outer contour and the same shape respectively. Each lamella 23 can be used as outer lamella 23a and also as inner lamella 23i after its production.

Two lamellae 23 that are directly adjacent in transverse direction Q together limit a flow channel 26 arranged therebetween. The number of flow channels 26 is by one less than the number of lamellae 23. Each inner lamellae 23i is directly adjacent to two flow channels 26 and separates these flow channels 26 from one another. Each outer lamellae 23a only limits one single flow channel 26.

Each flow channel 26 has a first channel opening 27 at the first opening 21 of the lamellae arrangement 20 and a second channel opening 28 at the second opening 22 of the lamellae arrangement. In flow direction S the first channel opening 27 and the second channel opening 28 of each flow channel 26 are arranged in alignment in the embodiment, as is particularly apparent from the dashed line in FIG. 4.

Each lamella 23 has a first edge 29 arranged at the first opening 21 or at the first channel opening 27 and a second edge 30 arranged at the second opening 22 or at the second channel opening 28. The first edge 29 and the second edge 30 extend in a height direction H orthogonal to the flow direction S and orthogonal to the transverse direction Q along a straight line.

Each lamella 23 has in addition a third edge 31 and a fourth edge 32 that are arranged with distance and preferably with constant distance in height direction H. The third edge 31 and the fourth edge 32 are arranged in alignment in height direction. The third edge 31 and the fourth edge 32 have a wave-shaped extension between the first edge 29 and the second edge 30. In so doing, the lamella 23 has multiple and according to the embodiment three bends 35.

At each bend 35 the lamella 23 forms on one side surface a concave depression and on the opposite side surface a convex elevation. The flow channel 26 limited by two lamellae 23 therefore has no straight, but an extension between the first channel opening 27 and the second channel opening 28 that is bent multiple times. Therefore gas G cannot flow along a straight line along the flow channel 26 between the channel openings 27, 28, but is deflected multiple times in its flow direction according to the number of bends 25 of the lamellae 23. The path that the gas G has to travel along the flow channel 26 is, therefore, larger than the distance between the first channel opening 27 and the second channel opening 28 in flow direction S.

With view onto the third edge 31 or the second edge 32 the lamella 23 has a wave-shaped extension having a curvature at each bend 35 respectively. Preferably the lamella 23 is realized without angles or sharp bends, which results in an improved gas flow through the flow channel 26. Alternatively or additionally, each lamella 23 can comprise one or more sharp bends between the first edge 29 and the second edge 30 as well.

Preferably each lamella 23 has a constant wall thickness d—apart from tolerances that are necessary due to manufacturing technology. The wall thickness d is preferably smaller than 2 mm, further preferably smaller than 1 mm and further preferably smaller than 0.7 mm.

In the embodiment the distance of the lamellae 23 in transverse direction Q corresponds to a channel width b. The channel width b is constant in one embodiment (FIG. 4).

At the first opening 21 facing the environment 13 the pressure relief device 18 can comprise a gas permeable cover 36. In the embodiment cover 36 is a perforated plate having a plurality of holes 37. Gas G and water W can reach the lamellae arrangement 20 through the holes 37. A sufficient protection from spray water, splash water or hose water cannot be achieved by means of cover 36. Cover 36 serves mainly to protect the lamellae arrangement 20 from damages due to mechanical influences, because the lamellae 23 are very thin and can be deformed easily.

The lamellae arrangement 20 provides protection from ingress of water W into interior 12 and can preferably in addition provide a flameproof condition. This is achieved by means of the configuration of the lamellae 23 and the flow channels 26 limited by the lamellae.

For the optional achievement of a flameproof condition, the flow cross-section of the flow channels 26 in relation to the curved flow length through a flow channel 26 is sufficiently small, such that hot gases, sparks or flames are extinguished or cooled before they can enter into the environment 13 out of the interior 12. In doing so, it is avoided that an explosive atmosphere in the environment 13 can be ignited.

If water W in the form of spray water, splash water or hose water hits the first opening 21, individual water drops are not able to pass from the first channel opening 27 to the second channel opening 28 through the lamellae arrangement 20 along a straight line, but hit onto a side wall of a lamella 23 adjacent to a flow channel 26. The accumulating water drops form a water accumulation and thereby get into contact with both lamellae 23 limiting the flow channel 26. Due to the adhesion force of the accumulation of water W inside a flow channel and the adjacent lamellae 23, it is avoided that water W completely passes through the flow channel 26 and into the interior 12.

The accumulation of water W that builds up inside a flow channel is schematically illustrated in FIGS. 2 and 6 for the first embodiment of the pressure relief device 18 described so far. In FIG. 1 block arrows indicate that water W may pass through the cover 36 into the lamellae arrangement 20, but does not enter into interior 12.

Water W that accumulates inside a flow channel 26 can evaporate over time, for example, and completely unblock the flow channel 26 again.

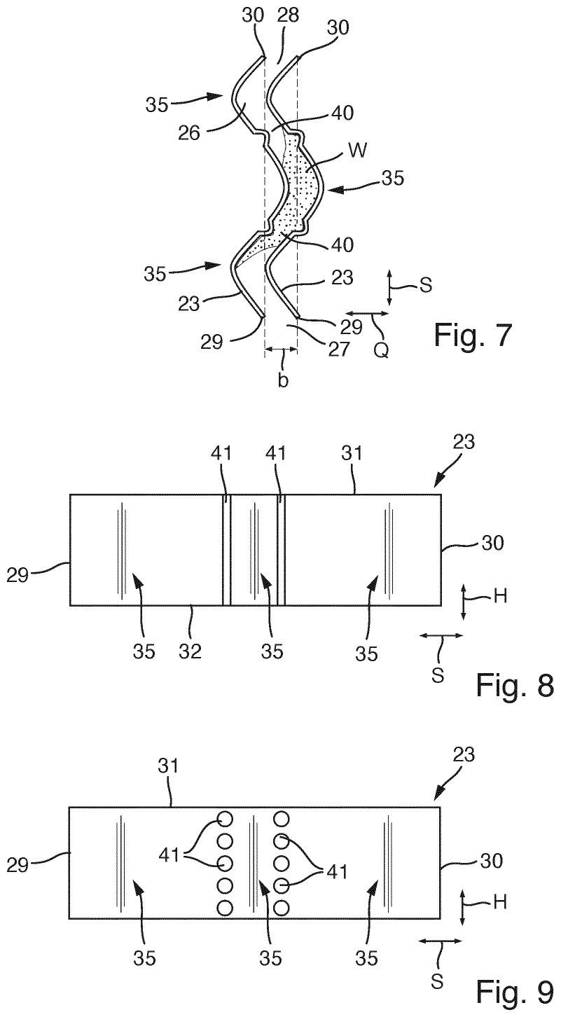

In FIG. 7-9 additional embodiments for configuration of lamellae 23 are schematically illustrated. In these embodiments each flow channel 26 has a maximum channel width b at the first channel opening 27 and/or the second channel opening 28. Between the first channel opening 27 and the second channel opening 28 each flow channel 26 comprises at least one narrow 40 with reduced flow cross-section or reduced channel width b in transverse direction (FIG. 7). Due to the at least one narrow 40, sticking of a water accumulation W on both lamellae 23 is also effected in case of smaller amounts of water W, such that the adhesion forces increase and water W does not exit out of the second channel opening 28 arranged at the second opening 22.

The at least one narrow 40 can be realized by at least one projection 41 that projects from a side wall of a lamella 23 facing the flow channel 26 and thereby reducing the flow cross-section and/or the channel width in transverse direction Q. The at least one projection 41 can be preferably manufactured by deformation of a lamella 23, e.g. by stamping. In the area of the at least one projection 41 the wall thickness d of the lamella 23 can be modified and particularly reduced compared with the wall thickness d at a section without projection 41.

As it is illustrated in FIGS. 8 and 9, a lamella 23 can comprise a projection 41 extending in height direction H completely along the lamella 23 for forming a respective narrow (FIG. 8). If the projection 41 is produced by deformation or stamping, it is convex on one side and groove-shaped concave on the other side.

In addition or as an alternative, at the narrow 40 multiple individual projections 41 that are distanced from each other can be produced respectively that can, for example, extend in a row in height direction H along the lamella 23 (FIG. 9). Each projection 41 can have the shape of a ball scraper or can have another arbitrary geometrical form. Also this multiplicity of projections 41 at each narrow can be produced by means of deformation or stamping.

If the lamellae 23 are produced from plastic, e.g. by means of injection molding, a projection 41 can also be manufactured during injection molding and thus by means of primary shaping. Also, the lamellae 23 can consist of a metallic alloy and can be produced from a steel sheet by means of bending and/or deformation, for example.

The lamellae arrangement 20 has a box-shaped contour in all of the embodiments. The first edges 29 of all of the lamellae 23 contact a common first plane at the first opening 21. All of the second edges 30 contact a common second plane at the second opening 22. The first plane and the second plane are orientated preferably parallel to each other. All of the third edges 31 extend preferably in a common third plane and all of the fourth edges 32 extend preferably in a common fourth plane. According to the example the third plane and fourth plane are orientated parallel to one another. In addition, the third plane and the fourth plane can be orientated orthogonal to the first plane and the second plane.

As it is illustrated in FIG. 2 by way of example, the lamellae 23 can be configured symmetrically with reference to a center plane M. According to the embodiment, the center plane M is arranged in the center between the first opening 21 or the first plane and the second opening 22 or the second plane and extends orthogonal to the flow direction S.

The lamellae 23 can have a surface that can be wetted with water, at least partially or completely. The material and/or the surface structure, particularly its roughness, can be defined such that the surface of the lamellae 23 can be wetted. A contact angle between a water drop and the lamella surface can be smaller than 90° or smaller than 60° or smaller than 30°. The indications refer to an air atmosphere at 20° C. and 1013 mbar.

The present disclosure refers to a pressure relief device 18 for an explosion-proof housing 10. The pressure relief device 18 has a lamellae arrangement 20 having a plurality of lamellae 23. The lamellae 23 are arranged in a transverse direction Q with distance to one another and thereby limit flow channel 26 between two lamellae 23 respectively. Each flow channel 26 establishes a flow connection between a first opening 21 and a second opening 22 of the lamellae arrangement 20 that are arranged with distance to one another in flow direction S. Each flow channel 26 has a non-straight preferably meandering or wave-shaped extension between the first opening 21 and the second opening 22 and can be flameproof as an option. Water drops that accumulate inside the flow channel 26 are retained due to the contact with the two adjacent lamellae 23 due to adhesion forces. In doing so, the pressure relief device is configured as protection against throughflow of water W without additional measures.

### LIST OF REFERENCE SIGNS

10 explosion-proof housing
11 housing wall
12 interior
13 environment
14 electric and/or electronic devices
18 pressure relief device
19 wall opening
20 lamellae arrangement
21 first opening
22 second opening
23 lamellae
23a outermost lamellae
23i innermost lamellae
26 flow channel
27 first channel opening
28 second channel opening
29 first edge
30 second edge
31 third edge
32 fourth edge
35 bend
36 cover
37 hole
40 narrow
41 projection
b channel width
d wall thickness
H height direction
M center plane
Q transverse direction
S flow direction

1. A pressure relief device configured to be used in a gas flow path between an interior of an explosion-proof housing and an explosive environment, the pressure relief device, comprising:
a lamellae arrangement comprising multiple lamellae, wherein the lamellae arrangement comprises a first opening and a second opening that is in flow connection with the first opening in a flow direction,
wherein the multiple lamellae extend between the first opening and the second opening, wherein each lamella of the multiple lamellae has multiple bends and/or sharp bends and wherein two directly adjacent lamellae of the multiple lamellae limit a non-straight flow channel respectively.

2. The pressure relief device according to claim 1, wherein the lamellae arrangement has two outer lamellae and at least one inner lamella arranged between the two outer lamellae.

3. The pressure relief device according to claim 1, wherein the at least one inner lamella directly adjoins two flow channels.

4. The pressure relief device according to claim 2, wherein the two outer lamella directly adjoins exactly one flow channel.

5. The pressure relief device according to claim 1, wherein each lamella of the multiple lamellae comprises at least three bends and/or sharp bends.

6. The pressure relief device according to claim 1, wherein all of the lamellae of the multiple lamellae are arranged symmetrically to a center plane, wherein the center plane is arranged between the first opening and the second opening.

7. The pressure relief device according to claim 1, wherein each lamella of the multiple lamellae has a first edge assigned to the first opening and a second edge assigned to the second opening.

8. The pressure relief device according to claim 7, wherein the first edge and the second edge are connected with one another via a non-linearly extending third edge and a non-linearly extending fourth edge.

9. The pressure relief device according to claim 8, wherein the first edge contacts a common first plane, the second edge contacts a common second plane, the third edges contacts a common third plane and the fourth edges contacts a common fourth plane.

10. The pressure relief device according to claim 1, wherein the flow channel comprises a constant channel width orthogonal to the flow direction.

11. The pressure relief device according to claim 10, wherein the flow channel comprises a narrow orthogonal to the flow direction at which the constant channel width is reduced orthogonal to the flow direction.

12. The pressure relief device according to claim 11, wherein the narrow is formed by means of a projection on at least one of the two directly adjacent lamellae limiting the flow channel.

13. The pressure relief device according to claim 1, wherein the flow channel has a first channel opening at the first opening and a second channel opening at the second opening the first channel opening and the second channel opening being arranged in alignment with the flow direction.

14. The pressure relief device according to claim 1, wherein each lamella of the multiple lamellae has a constant wall thickness.

15. The pressure relief device according to claim 1, wherein the pressure relief device is configured for installation in a wall opening of the explosion-proof housing.

16. The pressure relief device according to claim 1, wherein the flow channel is flameproof due to a ratio of the flow channel cross-section divided through a flow path length.

17. The pressure relief device according to claim 3, wherein the two outer lamella directly adjoin exactly one flow channel.

18. The pressure relief device according to claim 17, wherein each lamella of the multiple lamellae comprises at least three bends and/or sharp bends.

19. The pressure relief device according to claim 18, wherein all of the lamellae of the multiple lamellae are arranged symmetrically to a center plane, wherein the center plane is arranged between the first opening and the second opening.

20. The pressure relief device according to claim 19, wherein each lamella of the multiple lamellae has a first edge assigned to the first opening and a second edge assigned to the second opening.
